(19) United States
(12) Patent Application Publication
(10) Pub. No.: US 2006/0006403 A1
(43) Pub. Date: Jan. 12, 2006

(54) Optical module

(76) Inventors: Naoki Matsushima, Yokohama (JP); Kenji Yoshimoto, Yokohama (JP); Hiroyasu Sasaki, Yokohama (JP); Masanobu Okayasu, Yokohama (JP); Toshiaki Takai, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/135,408

(22) Filed: May 24, 2005

(30) Foreign Application Priority Data
Jul. 6, 2004 (JP) 2004-199346

(51) Int. Cl. H01L 29/22

(52) U.S. Cl. 257/99; 257/79; 257/433

(57) ABSTRACT

There is provided an optical module in which electrical wirings in a module package are simplified without increasing a manufacturing cost. A light emitting element is mounted on a substrate having electrical wirings therein. In the substrate, electrodes connected to the electrical wirings are formed at a side where the light emitting element is mounted. The light emitting element and the electrodes of one ends of the wirings are wire-bonded to each other and one ends of leads and the electrodes the other ends of the wirings are wire-bonded to each other.

### CLAIM OF PRIORITY

The present application claims priority from Japanese patent application serial no. 2004-199346, filed on Jul. 6, 2004, the content of which is hereby incorporated by reference into this application.

### BACKGROUND OF THE INVENTION

1. Field of the Invention

The present invention relates to an optical module, and more particularly, to a small optical module in which electrical wirings in a module package are simplified.

2. Description of the Related Art

As a demand of a marketplace in an optical communication system, there is miniaturization of size of an optical communication module. On the other hand, the optical communication module tends to be multi-functional and a plurality of wirings for electrically connecting various components to an outside of a package need to be provided. Accordingly, the number of leads in the module tends to be increased.

As a means for satisfying the above demand, there is a method of arranging leads included in the package of the optical communication module at a specific location. For example, if the leads are arranged at only one sidewall of a module package having a rectangular parallelepiped shape, the module can be arranged at an end of an optical transceiver when the optical module is mounted on the optical transceiver, thereby improving degree of freedom in arrangement of each component or degree of freedom in electrical wiring design. Also, since the leads exit from only one side thereof, it is advantageous in that the module size is reduced.

Japanese Patent Laid-Open No. 2003-060281 describes about a small light emitting element module capable of surface-mounting, and a method of manufacturing the same.

However, in a case of a package structure with leads formed at only one side, electrical wirings in the optical module package become complicated. Since optical and configurational restrictions have priorities in determining the arrangement of each functional component in the package, it is difficult to provide the electrical wirings in a simplified shape.

Particularly, in a case in which there are various electrodes at a side where leads do not exist with respect to an optical axis, it is necessary that they be connected by long bonding wires or a long relay board be formed. In this structure, the manufacturing process is complicated, and further there is a possibility that failure of the wirings is increased.

### SUMMARY OF THE INVENTION

In order to solve the above-mentioned problems, in the present invention, a functional component is mounted on a substrate(functioning as a pedestal) in which inner wirings are formed and electrodes connected to the wirings are formed at a side where the functional component is mounted. The functional component and the electrodes provided at one ends of the wirings are connected to each other and one ends of the leads and the electrodes provided at the other ends of the wirings are connected to each other.

According to the invention, an optical module, having leads formed at only one side, of which manufacturing process is simple and in which there is little possibility of a failure such as wire disconnection.

### BRIEF DESCRIPTION OF THE DRAWINGS

Preferred embodiments of the present invention will now be described in conjunction with the accompanying drawings, in which;

FIG. 1 is a side view and a plan view of a light emitting element module according to a first embodiment of the present invention;

FIG. 2 is a side view and a plan view of a substrate according to the first embodiment of the present invention;

FIG. 3 is a side view and a plan view of a light emitting element module according to a second embodiment of the present invention;

FIG. 4 is a side view and a plan view of a light emitting element module according to a third embodiment of the present invention;

FIG. 5 is a side view and a plan view of a light emitting element module according to a fourth embodiment of the present invention; and

FIG. 6 is a plan view of a transceiver module according to a fifth embodiment of the present invention.

### DESCRIPTION OF THE PREFERRED EMBODIMENTS

Hereinafter, embodiments of the present invention will be described with reference to the accompanying drawings.

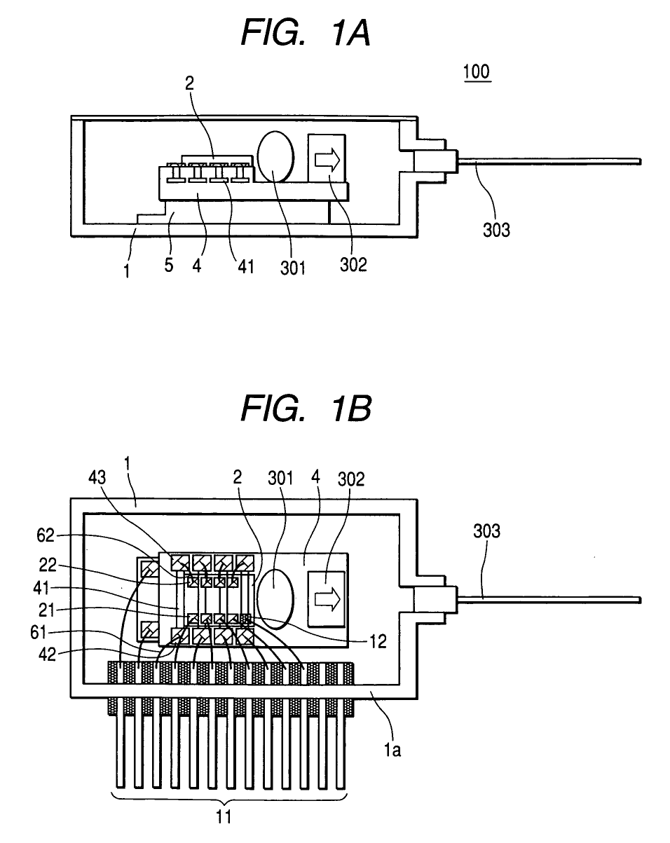

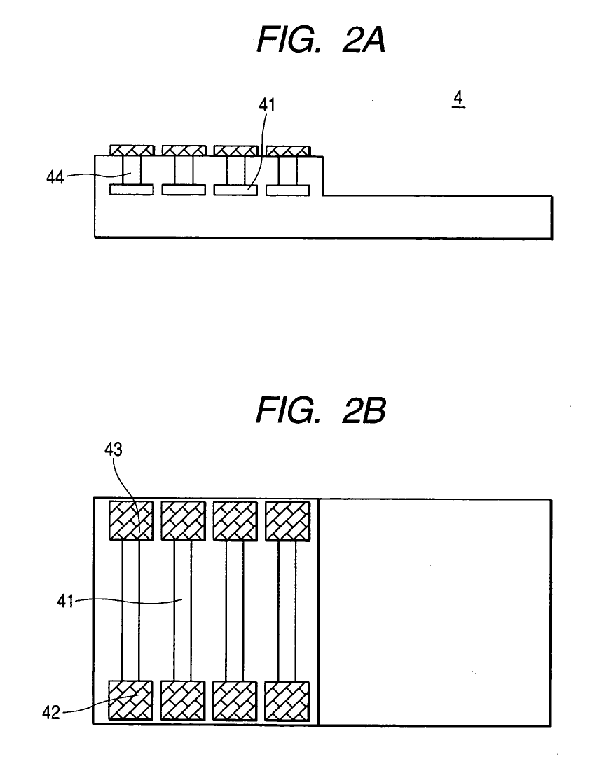

First, a light emitting element module according to a first embodiment of the present invention will be described with reference to FIGS. 1 and 2. Here, FIG. 1 shows the light emitting element module according to the first embodiment of the present invention, and FIG. 1A is a side view thereof and FIG. 1B is a plan view thereof. Also, FIG. 2 show a substrate of the first embodiment, FIG. 2A is a side view thereof and FIG. 2B is a plan view thereof. Further, for simplicity of the figures, there are portions which are shown in the plan view but are not shown in the side view, and vice versa. This is the same in the other embodiments and what has been previously described will be omitted in the other embodiments.

In FIG. 1, a light emitting element 2 is an element for emitting a plurality of different wavelengths, which is called as a tunable laser diode. The light emitting element 2 has a plurality of waveguides (not shown) to emit light having a wide range of wavelength and two electrode groups 21 and 22 corresponding to each waveguide. The electrodes are formed at both sides with the waveguide therebetween. The plurality of waveguides is integrated into one waveguide (not shown) at a front emitting side in the light emitting element 2.

A light beam emitted form the light emitting element 2 is focused by a lens 301 located ahead thereof, passes through an isolator 302 for suppressing light reflected toward the light emitting element 2, and is coupled to an optical fiber 303 to be transmitted to an outside of the module.

A light emitting element module 100 is configured such that leads 11 for inputting electrical signals from an outside of a module package 1, having a rectangular parallelepiped shape, to an inside thereof and for outputting the electrical signals from the inside to the outside thereof penetrates a wall 1a which is one side of the package 1.

The light emitting element 2 is attached to a substrate 4 by soldering. Front and rear surfaces of the substrate 4 are formed with metallization layers, respectively (not shown). By using the metallization layers, the substrate 4 is mounted on a thermo-cooler 5 by the soldering connection and the thermo-cooler 5 is fixed to a bottom portion of the package 1 by soldering. Here, composition of the soldering (that is, melting point) is adequately selected by an order of the connection. The role of the thermo-cooler 5 is to cool the light emitting element 2 in which heat is generated due to the light emission and to control an oscillating wavelength by varying a temperature of the light emitting element 2.

In other words, the substrate 4 mounted with the light emitting element 2 serves as a heat transfer path between the light emitting element 2 and the thermo-cooler 5. Accordingly, it is preferable that a member having a low thermal resistance is used as the substrate 4 in order to efficiently emit the heat from the light emitting element 2. In the present embodiment, a ceramic substrate mainly composed of AlN (aluminum nitride), which is an insulating material having a low thermal resistance, is used. The substrate 4 shown in FIG. 2 includes electrical wirings 41 in which tungsten is used as a wiring material. Each electrode of an electrode group 42 is electrically connected to the corresponding electrode of an electrode group 43 through a via(also described as a via hole) 44 just below the electrode, an inner electrical wiring 41, and a via 44 just below the electrode of the electrode group 43. Also, the substrate 4 is provided with a step to match an optical axis of the light emitting element 2, the lens 301 and the isolator 302. This step is formed by laminating a ceramic sheet. Accordingly, if wirings are formed on the ceramic sheet, the wirings 41 can be formed only by adding a process of embedding the via in a process of manufacturing the substrate 4.

Referring back to FIG. 1, by using the substrate 4, the electrode group 21 at a lead side of the light emitting element 2 can be directly wire-bonded to leads 11 and the electrode group 22 at a non-lead side (a side where leads do not exit with respect to the optical axis) of the light emitting element 2 can be wire-bonded to the very near electrode group 43 of the substrate 4. Since the electrode group 22 at the non-lead side of the light emitting element 2 is connected to the electrode group 44 of the substrate 4 closest to the leads 11 through the inner electrical wirings 41 of the substrate 4, the electrode group 44 is wire-bonded to the leads 11. Thereby, electrical connections can be made at a concentration portion of the bonding wires, without using long bonding wires. In addition, since the substrate for heat emission, which has been conventionally needed, can also perform a function of the electrical wirings, the number of components is not increased.

By wire-bonding a thermistor 12 formed on the light emitting element 2, terminals of the thermo-cooler 5 and the leads 11, the electrical wirings are completed. Here, it has been confirmed that, although bonding wires between the terminals of the thermo-cooler 5 and the leads 11 are long, there is no problem because interference with the other wires is little.

The light emitting element module 100 of the present invention is mounted with the light emitting element 2 having a plurality of the waveguides to correspond to a wide range of wavelength. Since the plurality of waveguides is provided with wirings, a waveguide can be selected from the outside to vary the wavelength in a wide range. Also, even by using only one waveguide, the wavelength can be varied in a narrow range by the thermistor 12, the thermo-cooler 5 and an external controlling circuit. Accordingly, the light emitting element module 100 of the present invention can widely vary the wavelength with high precision.

According to the present invention, a small light emitting element module, in which leads exit from only one side of the package, can be obtained.

In addition, as a material of the substrate 4, materials other than AlN may be used, but a material having a low thermal resistance is preferably used. As a suitable material substituting the AlN, there is SiC (silicon carbide), Si (silicon) or alumina. Also, with respect to an inner wiring material, materials other than Tungsten may be used if it does not have an extremely high electrical resistance.

Moreover, with respect to an optical structure, structures other than that of the embodiment may be used. For example, plural lenses may be used, or a light emitting element may be directly coupled to an optical fiber without using the lens. Further, an isolator may not be used if an effect due to reflected light can be avoided. In the present invention, a Peltier element is used as the thermo-cooler. The Peltier element becomes a thermo-heater in accordance with a direction of a flowing current, and is controlled to perform heating if a surrounding temperature is extremely low.

In the present embodiment, as a case of the light emitting element module, a metal wall type light emitting element module, in which leads pass through a hole formed in a side of a metal frame and which is hermetically sealed by glass, is used. However, the case is not limited to the metal wall type. For example, a field through type light emitting element module, in which a ceramic substrate formed with an electrical wiring is bonded to a metal frame, may be used. In this case, wirings formed on the ceramic substrate are leads. Modification of the above-mentioned embodiment is the same in the other embodiments.

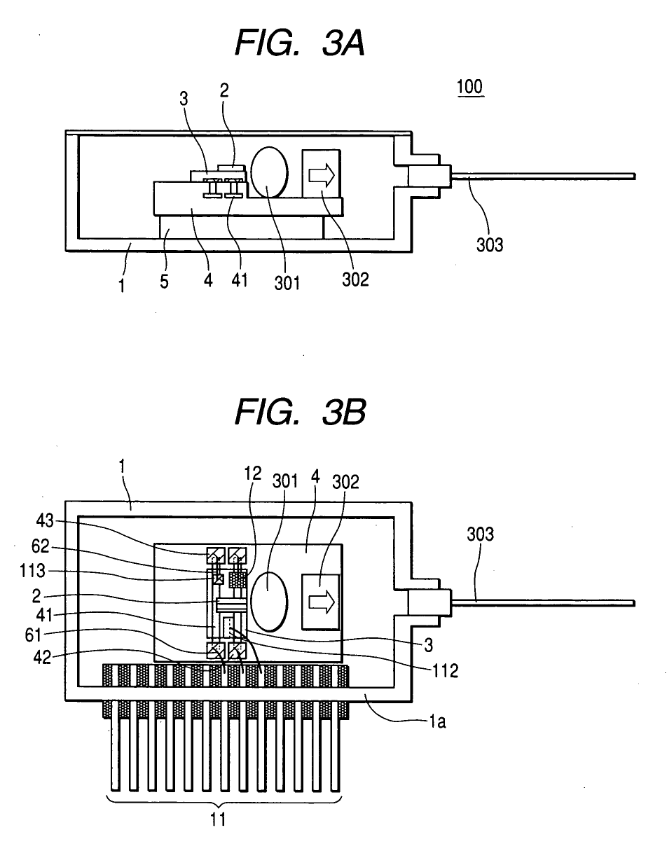

Next, the light emitting element module according to a second embodiment of the present invention will be described with reference to FIG. 3. Here, FIG. 3 shows the light emitting element module according to the second embodiment of the present invention, and FIG. 3A is a side view thereof and FIG. 3B is a plan view thereof.

In FIG. 3, the light emitting element 2 is attached to the substrate 4 through a sub-assembly substrate 3 by soldering. The substrate 4 is mounted on the thermo-cooler 5 by the soldering connection and the thermo-cooler 5 is fixed to a bottom portion of the package 1 by soldering.

The light emitting element module 100 of the second embodiment is configured to have leads 11 provided at one side 1a of the module package 1. The light emitting element 2 of the present embodiment is a laser diode with a single wavelength. The light emitting element 2 is mounted on the sub-assembly substrate 3 to evaluate light emitting characteristic of the light emitting element 2 before it is mounted on the substrate 4. There is a yield as an evaluating test item, and when there is a problem in the light emitting element 2, the light emitting element 2 must be separated form the sub-assembly substrate 3. On this account, the sub-assembly substrate 3 preferably has a low thermal resistance. Also, in consideration of a case in which the light emitting element 2 can not be separated from the sub-assembly substrate 3, the sub-assembly substrate 3 is preferably low in price. Further, since the light emitting element 2 is mounted thereon, a thermal expansion coefficient of the sub-assembly substrate 3 should be close to that of the semiconductor. Accordingly, in the present embodiment, AlN is used as a material of the sub-assembly substrate 3.

The sub-assembly substrate 3 is mounted with a thermistor 12 for monitoring a temperature of the light emitting element 2. Furthermore, electrical wirings 112 for supplying electrical signals to the light emitting element 2 are provided. In order to efficiently arrange these components on the sub-assembly substrate 3, it is preferable that they are symmetrically provided with respect to an optical axis of the light emitting element 2. In the present embodiment, the thermistor 12 is arranged at a non-lead side.

As the substrate 4, similarly to the first embodiment, a member mainly composed of AlN is used in order to efficiently emit the heat from the light emitting element 2. Electrical wirings 41, in which Tungsten is used as a wiring material, are provided in the substrate 4. Electrodes of the electrode group 42 at a lead side and electrodes of the electrode group 43 at a non-lead side in the substrate 4 are electrically connected to each other through the electrical wirings 41 formed in the substrate 4. The leads 11 and the electrode group 42 are electrically connected to each other by bonding wires 61, and the electrode group 43 at a non-lead side of the substrate 4, the electrode 113 for the thermistor 12 and the thermistor 12 are connected to one another by bonding wires 62. Thereby, the electrode 113 for the thermistor 12 and the leads 11 of the package 1 can be electrically connected to each other.

According to the present embodiment, electrical connections can be made without employing a complicate form, such as using long bonding wires. In addition, since the substrate 4 for heat emission also performs a function of the electrical wirings, the number of components is not increased. Accordingly, a small light emitting element module, in which leads exit from only one side of the package, can be obtained.

Furthermore, although a component, in which electrical connections are made by using the inner wirings 41, is used as the thermistor 12, others may be used. For example, inner wirings may be used in the electrical wirings for supplying a current to the light emitting element 2. Also, although an inner layer may be provided in the sub-assembly substrate 3, it makes it difficult to separate the light emitting element 2.

Moreover, a material of the sub-assembly substrate 3 is not limited to AlN. Specifically, SiC, Si (silicon) or alumina may be used.

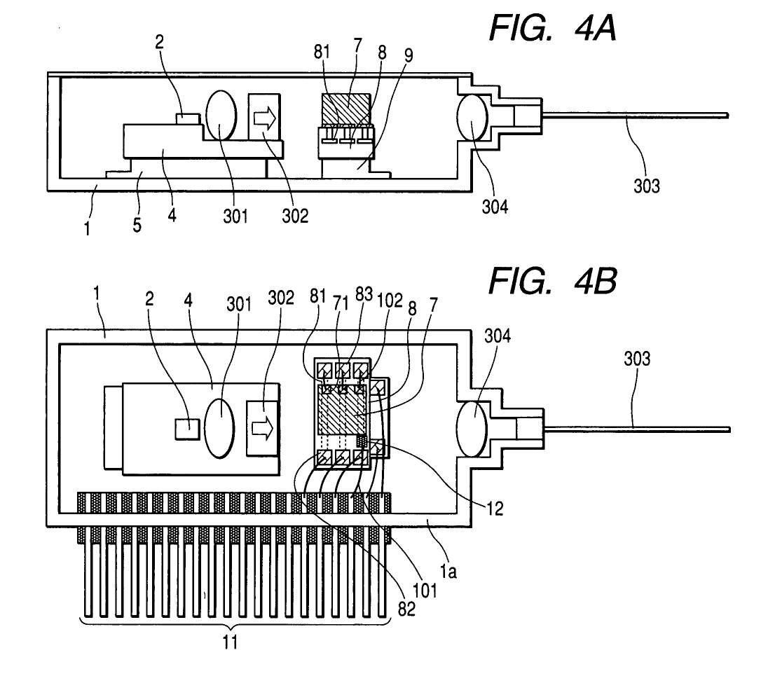

Next, the light emitting element module according to a third embodiment of the present invention will be described with reference to FIG. 4. Here, FIG. 4 shows the light emitting element module according to the third embodiment of the present invention, and FIG. 4A is a side view thereof and FIG. 4B is a plan view thereof. Further, as mentioned above, wiring at a vicinity of the light emitting element is not shown.

The light emitting element module 100 shown in FIG. 4 includes a light emitting element 2 and a wavelength locker 7. The wavelength locker 7 consists of two photodiodes and an etalon filter, and it is a component for monitoring a light intensity before and after the light emitted from the light emitting element 2 transmits the etalon filter to thereby stabilize a wavelength. A light beam emitted from the light emitting element 2 becomes collimated light by a lens 301 located ahead thereof and is incident on the wavelength locker 7 through an isolator 302. The light beam transmitting through the wavelength locker 7 is focused by a lens 304 and is coupled to an optical fiber 303 to be delivered to an outside of the module.

The light emitting element module 100 is configured such that leads 11 are formed at a sidewall 1a of the module package 1. An electrode group 71 of the photodiode constituting the wavelength locker 7 is arranged at a side (at a non-lead side) distant from the sidewall 1a through which the leads 11 penetrate. The wavelength locker 7 is attached to a substrate 8 by soldering, and the substrate 8 is mounted on a thermo-cooler 9 by soldering connection. Further, the thermo-cooler 9 is fixed to a bottom portion of the package 1 by soldering. Here, the thermo-cooler 9 controls a temperature of the wavelength locker 7 and a monitoring wavelength. An external controlling device (not shown) controls the temperature of the thermo-cooler 5 mounted with the light emitting element 2 so that the light intensity ratios before and after transmitting the etalon filter of the wavelength locker 7 can be constant.

The substrate 8 has inner electrical wirings 81 therein. In the present embodiment, alumina is used as an insulating material of the substrate 8 and tungsten is used as a material of the inner wirings. But, similarly to the first embodiment, other members may be used. Electrodes 82 at a lead side of the substrate 8 are electrically connected to electrodes 43 at a non-lead side through the electrical wirings 81 formed in the substrate 4. The leads 11 and the electrodes 82 are electrically connected to each other by boding wires 91, and electrodes 83 and electrodes 71 of the photodiode constituting the wavelength locker 7 are connected to each other by bonding wires 92. Thereby, the electrodes 71 of the wavelength locker 7 and the leads 11 of the package 1 can be electrically connected to each other, and thus the electrical wirings can exit to an outside of the module package 1.

In this specification, a light emitting element and a wavelength locker are called as functional components. Also, the functional component is not limited thereto, but it is a general term of components which have electric terminals and are placed on an optical axis. The functional component includes a light receiving element, and an optical modulator described below.

According to the present embodiment, electrical connections can be made without employing a complicate form, such as using long bonding wires. In addition, since the substrate for heat coupling with the thermo-cooler also performs a function of the electrical wirings, the number of components is not increased. Accordingly, a small light emitting element module, in which leads exit from only one side of the package, can be obtained.

With respect to an optical structure, structures other than the structure shown in the third embodiment may be used. For example, a structure in which convergence light is allowed to pass the wavelength locker 7 without using the lens 304 may be used. Furthermore, an isolator may not be used if an effect due to reflected light can be avoided. Also, although the wavelength locker 7 according to forward light of the light emitting element 2 is illustrated in the third embodiment, a wavelength locker according to backward light thereof may be used.

In the present embodiment, the Peltier element is used as a thermo-cooler. The Peltier element becomes a thermo-heater in accordance with a direction of a flowing current, and is controlled to perform heating in accordance with a wavelength to be monitored.

In addition, although the light emitting element and the wavelength locker are accommodated in the same case in the present embodiment, a structure in which they are accommodated in different cases and are coupled to each other using an optical fiber may be considered. In this case, a module accommodating the wavelength locker is called as a wavelength locker module. The light emitting element module and the wavelength locker module are generally called optical modules. Further, the optical module includes a light receiving element module and an optical modulator module, but it is not limited thereto.

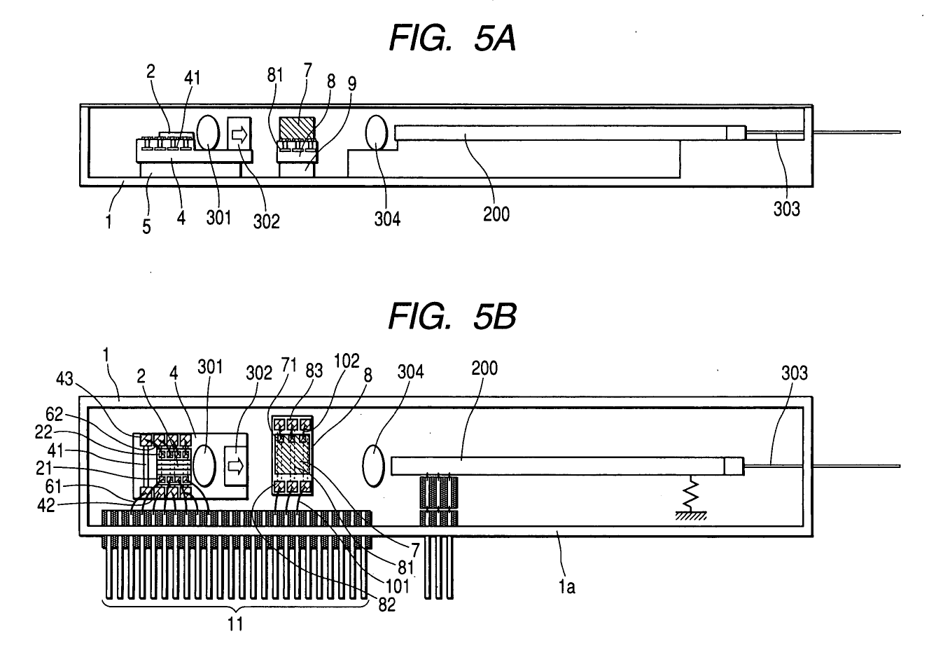

Next, the light emitting element module according to a fourth embodiment of the present invention will be described with reference to FIG. 5. Here, FIG. 5 shows the light emitting element module according to the fourth embodiment of the present invention, and FIG. 5A is a side view thereof and FIG. 5B is a plan view thereof.

FIG. 5 shows a light module 100 comprising a light emitting element 2, a wavelength locker 7 and a Mach-Zehnder modulator 201 in a module package 1. Light emitted from the light emitting element 2 becomes collimated light by a lens 301 and is incident on the wavelength locker 7 through an isolator 302. Light beam transmitting through the wavelength locker 7 is focused by a lens 304 and is incident on the Mach-Zehnder modulator 201. The light modulated by the Mach-Zehnder modulator 201 is transmitted to an outside of the module through an optical fiber 303.

The light emitting element 2 is a tunable light source and comprises a plurality of waveguides so as to emit light having a wide range of wavelength and a plurality of electrodes 21 and 22 corresponding to each waveguide. The electrodes are formed at both sides of the waveguide. The waveguide locker 7 monitors a wavelength of the light emitted from the light emitting element 2 before and after transmitting an etalon filter, by using two photodiodes. The Mach-Zehnder modulator 200 has a function for modulating continuous light emitted form the light emitting element 2 into signal light, and the length of an optical axis thereof is several tens mm.

The module 100 is configured such that leads 11 for inputting electrical signals from an outside to an inside of the package 1 and for outputting the electrical signals from the inside to the outside are provided in a sidewall 1a.

A mounting structure of the light emitting element 2 is that it is attached to the substrate 4 by soldering, similarly to the first embodiment. The substrate 4 is mounted on the thermo-cooler 5 by soldering connection and the thermo-cooler 5 is fixed to a bottom portion of the package 1 by soldering. Further, the light emitting element 2 may be mounted on the substrate 4 through the sub-assembly substrate, similarly to the second embodiment.

A ceramic substrate mainly composed of AlN (aluminum nitride) is used as a material of the substrate 4, similarly to the first embodiment. The substrate 4 has inner electrical wirings 41 therein. As a material of the wiring, tungsten is used. Electrode group 42 at a lead side and electrode group 43 at a non-lead side of the package 1 of the substrate 4 are electrically connected to each other through the electrical wirings 41 formed at the inside in the substrate 4.

Thereby, the leads 11 penetrating through a sidewall of the package and the electrode group 42 at the lead side are electrically connected to each other by bonding wires 61, and the electrode group 43 at a non-lead side and the electrode group 22 at a non-lead side of the light emitting element 2 are connected to each other by bonding wires 62. In this way, the electrodes 22 of the light emitting element 2 and the leads 11 of the package 1 can be electrically connected to each other, and thus the electrical wirings can exit to an outside of the module package 1. The electrode group 21 of the light emitting element 2 at a lead side is directly connected to the leads 11 by wire bonding.

An electrode group 71 of the photodiode of the wavelength locker 7 is arranged at the non-lead side. The wavelength locker 7 is attached to the substrate 8 by soldering. The substrate 8 is mounted on the thermo-cooler 9 by soldering connection and the thermo-cooler 9 is fixed to the bottom portion of the package 1 by soldering.

The substrate 8 has inner electrical wirings 81 therein. In the present embodiment, alumina (aluminum oxide) is used as an insulating material of the substrate 8 and tungsten is used as a material of the inner wirings. An electrode group 82 at a lead side of the substrate 8 is electrically connected to an electrode group 43 at a non-lead side through electrical wirings 81 formed in the substrate 4. The leads 11 penetrating through a sidewall of the package and the electrode group 82 at the lead side are electrically connected to each other by bonding wires 101, and an electrode group 83 at the non-lead side of the substrate 8 and the electrode group 71 of the photodiode constituting the wavelength locker 7 are connected to each other by bonding wires 102. Thereby, the electrode group 71 of the wavelength locker 7 and the leads 11 of the package 1 can be electrically connected to each other, and thus the electrical wirings can exit to an outside of the module package 1.

The Mach-Zehnder modulator 200 is made of LiNbO₃ crystal and can modulate continuous light, having a wide range of wavelength, emitted from the tunable light source (the light emitting element 2) into an optical signal having a transmission rate of 10 Gbits/s, by using an electrical signal having a transmission rate of 10 Gbits/s from an outside (not shown).

In the present embodiment, electrical connections can be made without employing a complicate form, such as using long bonding wires. In addition, since the substrate for heat emission also performs a function of the electrical wiring, the number of the components is not increased. Accordingly, a small light emitting element module, in which leads exit from only one side of the package, can be obtained.

Furthermore, although the inner wirings are provided at both of the light emitting element 2 and the wavelength locker 7 in the present embodiment, a structure in which the inner wirings are provided at only one of them may be employed. Also, with respect to an optical structure, methods other than the embodiment may be used. For example, a method for coupling convergence light from the lens 304 to an optical fiber to transmit the light by directly connecting the optical fiber to the Mach-Zehnder modulator may be used.

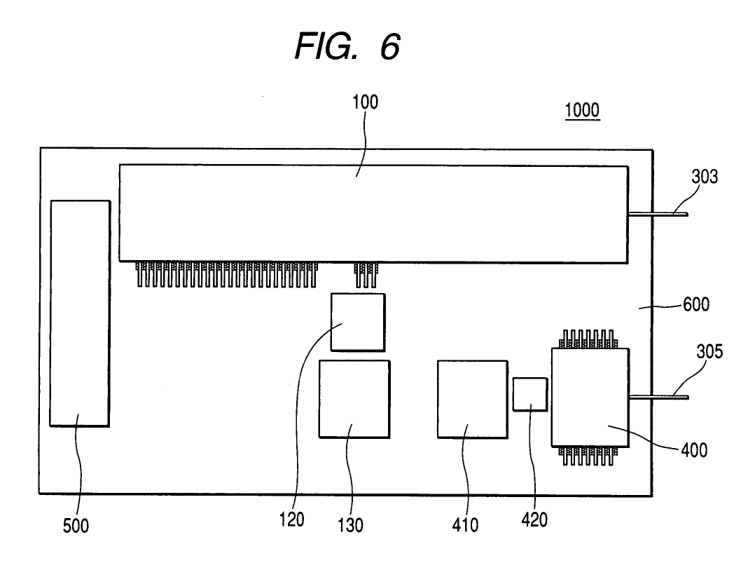

Next, a transceiver module according to a fifth embodiment of the present invention will be described with reference to FIG. 6. Here, FIG. 6 is a plan view of the transceiver module according to the fifth embodiment of the present invention.

An optical transceiver 1000 shown in FIG. 6 consists of a light emitting element module 100 illustrated in the fourth embodiment, a light receiving element module 400 and peripheral circuits. Four electrical signals, each having a transmission rate of 2.4 Gbits/s, input from a connector 500 are multiplexed to a signal having a transmission rate of 10 Gbits/s at a multiplexing IC 130, then is transmitted to the light emitting element module 100 through a driving IC 120 for outputting an modulated signal to the Mach-Zehnder modulator 200, and then an optical signal having a transmission rate of 10 Gbits/s is transmitted to the optical fiber 303.

An optical signal, having a transmission rate of 10 Gbits/s, transmitted from the optical fiber 305 is converted into an electrical signal in a light receiving element module 400, then passes through an amplifying IC 420, and then is divided into four signals, each having a transmission rate of 2.4 Gbits/s, in a demultiplexing IC 410 to be transmitted from the connector 500.

In the optical transceiver of the present invention, since the light emitting element module 100, in which leads are arranged at only one side of the package, is used, the light emitting element module 100 can be positioned at the end of the substrate 600 and thus the optical transceiver can be miniaturized.

Moreover, the package of the light receiving element, in which the leads are positioned at only one side thereof, may be used. Further, a light transmitter module, in which the light emitting element and the peripheral circuits are mounted on the substrate, may be used. Similarly, a light receiver module, in which the light receiving element having the leads provided at only one side of the package and the peripheral circuits are mounted on the substrate, may be used.

Here, the optical transceiver, the light transmitter module and the light receiver module all are optical modules.

1. An optical module comprising:
a case having leads that input and output electrical signals; and
a functional component accommodated in the case,
wherein said functional component is connected to a substrate formed with wirings therein,
said substrate has at least two electrodes, connected to said wirings, in a side connected to said functional component,
said functional component and said electrodes provided at one ends of said wirings are wire-bonded to each other, and
one ends of said leads and said electrodes provided at the other ends of said wirings are wire-bonded to each other.

2. An optical module comprising:
a case having leads that input and output electrical signals;
a thermo-cooler attached to said case;
a functional component having electrodes; and
a substrate that transfers heat between said thermo-cooler and said functional component,
wherein said substrate is formed with wirings therein, and
said electrodes and said leads are electrically connected to each other by said wirings.

3. An optical module comprising:
a case having leads that input and output electrical signals;
a functional component having electrodes; and
a Peltier element attached to said case that transfers heat between said case and said functional component,
wherein wirings electrically connected to said functional component are formed in a heat transfer path between said functional component and said Peltier element.

4. The optical module according to claim 1,
wherein said functional component is a laser diode.

5. The optical module according to claim 2,
wherein said functional component is a laser diode.

6. The optical module according to claim 3,
wherein said functional component is a laser diode.

7. The optical module according to claim 1,
wherein said functional component is a wavelength locker.

8. The optical module according to claim 2,
wherein said functional component is a wavelength locker.

9. The optical module according to claim 3,
wherein said functional component is a wavelength locker.

10. The optical module according to claim 1,
wherein said substrate is connected to said functional component through a sub-assembly substrate.

11. The optical module according to claim 2,
wherein said substrate is connected to said functional component through a sub-assembly substrate.

12. An optical module comprising:
a substantially rectangular parallelepiped case having leads that input and output electrical signals; and
a light emitting element having a plurality of waveguides and electrodes provided at both sides of an optical axis,
wherein said leads are connected to one side of said case.

13. An optical module comprising:
a substantially rectangular parallelepiped case having leads that input and output electrical signals and an optical fiber for outputting optical signals;
a light emitting element having a plurality of waveguides and electrodes provided at both sides of an optical axis;
a wavelength locker that monitors an optical output of said light emitting element; and
a modulator that modulates light passing through said wavelength locker,
wherein said leads are connected to one side of said case.

14. The optical module according to claim 12,
wherein said light emitting element is a tunable laser diode whose wavelength can be varied.

15. The optical module according to claim 13,
wherein said light emitting element is a tunable laser diode whose wavelength can be varied.

16. An optical module comprising:
a light emitting element module; and
a light receiving element module,
wherein said light emitting element module has a case having leads for inputting and outputting electrical signals; a functional component having electrodes; and a Peltier element attached to said case for transferring heat between said case and said functional component, and wirings electrically connected to said functional component are formed in a heat transfer path between said functional component and said Peltier element.
